(19) United States
(12) Patent Application Publication
(10) Pub. No.: US 2026/0106588 A1
(43) Pub. Date: Apr. 16, 2026

(54) SIGNAL PROCESSING CIRCUIT

(71) Applicant: FUJI ELECTRIC CO., LTD., Kawasaki-shi (JP)

(72) Inventor: Yoshinori KOBAYASHI, Matsumoto-city (JP)

(73) Assignee: FUJI ELECTRIC CO., LTD., Kawasaki-shi (JP)

(21) Appl. No.: 19/308,543

(22) Filed: Aug. 25, 2025

(30) Foreign Application Priority Data
Oct. 15, 2024 (JP) 2024-179778

(51) Int. Cl. H03F 3/45

(52) U.S. Cl. CPC H03F 3/456; H03F 3/45183; H03F 2203/45042; H03F 2203/45212; H03F 2203/45424

(57) ABSTRACT

A signal processing circuit, including: first and second operational amplifiers, each configured to perform offset adjustment and being selectable to operate as an amplifier circuit to output an output voltage; a comparator circuit comparing the output voltage and a predetermined voltage; and a control circuit that, upon completion of the offset adjustment of the first operational amplifier, causes the first operational amplifier to process an input signal, while causing the second operational amplifier to stop processing the input signal and perform the offset adjustment in response to a signal of a period, and upon completion of the offset adjustment of the second operational amplifier, causes the second operational amplifier to process the input signal, while causing the first operational amplifier to stop processing the input signal and to perform the offset adjustment in response to the signal of the period, each based on a comparison result of the comparator circuit.

### CROSS-REFERENCE TO RELATED APPLICATIONS

The present application claims priority pursuant to 35 U.S.C. § 119 from Japanese patent application number 2024-179778 filed on Oct. 15, 2024, the entire disclosure of which is hereby incorporated by reference herein.

### BACKGROUND

### Technical Field

The present disclosure relates to a signal processing circuit.

### Description of the Related Art

There have been operational amplifiers having a circuit to adjust an offset voltage (for example, Japanese Patent Application Publication No. 2007-299294, Japanese Patent Application Publication No. 2013-031089, Japanese Patent Application Publication No. 2009-033638, WO 00/057546, Japanese Patent Application Publication No. 2001-044770, and Japanese Patent Application Publication No. H11-088071).

In general, when a long period of time has elapsed after the offset voltage of such an operational amplifier is adjusted, the offset voltage may shift due to the influence of temperature and the like. As a result, the operational amplifier may not be able to process an input signal precisely.

### SUMMARY

A first aspect of the present disclosure is a signal processing circuit, comprising: a first operational amplifier and a second operational amplifier, each configured to perform offset adjustment thereof, and each being selectable to operate as an amplifier circuit to output an output voltage corresponding to an input voltage thereof; a comparator circuit configured to output a comparison result obtained by comparing the output voltage of the amplifier circuit and a predetermined voltage; and a control circuit configured to, upon completion of the offset adjustment of the first operational amplifier, cause the first operational amplifier to process an input signal of the signal processing circuit, while causing the second operational amplifier to stop processing the input signal and to perform the offset adjustment thereof in response to a signal having a predetermined period, based on the comparison result, and upon completion of the offset adjustment of the second operational amplifier, cause the second operational amplifier to process the input signal, while causing the first operational amplifier to stop processing the input signal and to perform the offset adjustment thereof in response to the signal having the predetermined period, further based on the comparison result.

A second aspect of the present disclosure is a signal processing circuit, comprising: an amplifier circuit configured to output an output voltage corresponding to an input voltage, using an operational amplifier; an adjustment circuit configured to adjust an offset of the operational amplifier, based on a value of an adjustment data; a comparator circuit configured to output a comparison result obtained by comparing the output voltage and a predetermined voltage; and a control circuit configured to perform a process of storing a first comparison result that is the comparison result of the comparator circuit in a first state in which the value of the adjustment data is set to a first value; storing a second comparison result that is the comparison result of the comparator circuit in a second state in which the value of the adjustment data is set to a second value; and storing a third comparison result that is the comparison result of the comparator circuit in a third state in which the value of the adjustment data is set to the first value, and subsequently determine whether the first comparison result and the third comparison result are the same.

### BRIEF DESCRIPTION OF THE DRAWINGS

FIG. 1 is a diagram illustrating an example of a configuration of a signal processing circuit 1.

FIG. 2 is a diagram illustrating an example of a configuration of a signal processing circuit 1 when an operational amplifier 10a is selected to operate as an amplifier circuit.

FIG. 3 is a diagram illustrating an example of a configuration of an operational amplifier 10a, 10b.

FIG. 4 is a diagram illustrating an example of a flowchart illustrating an operation of a signal processing circuit 1.

FIG. 5 is a diagram illustrating an example of a timing chart when an offset adjustment is completed within a period T.

FIG. 6 is a diagram illustrating an example of a timing chart when an offset adjustment is not completed within a period T.

### DETAILED DESCRIPTION

At least following matters will become apparent from the descriptions of the present description and the accompanying drawings.

The same or equivalent constituent elements, members, and the like illustrated in the drawings are given the same reference numerals, and repetitive description is omitted as appropriate.

Further, in an embodiment of the present disclosure, the term “connect” means a state of being “electrically connected” unless otherwise specified. Thus, the term “connect” includes not only the case where two components are connected by wiring, but also the case where two components are connected through a resistor, for example.

### ===Configuration of Signal Processing Circuit 1===

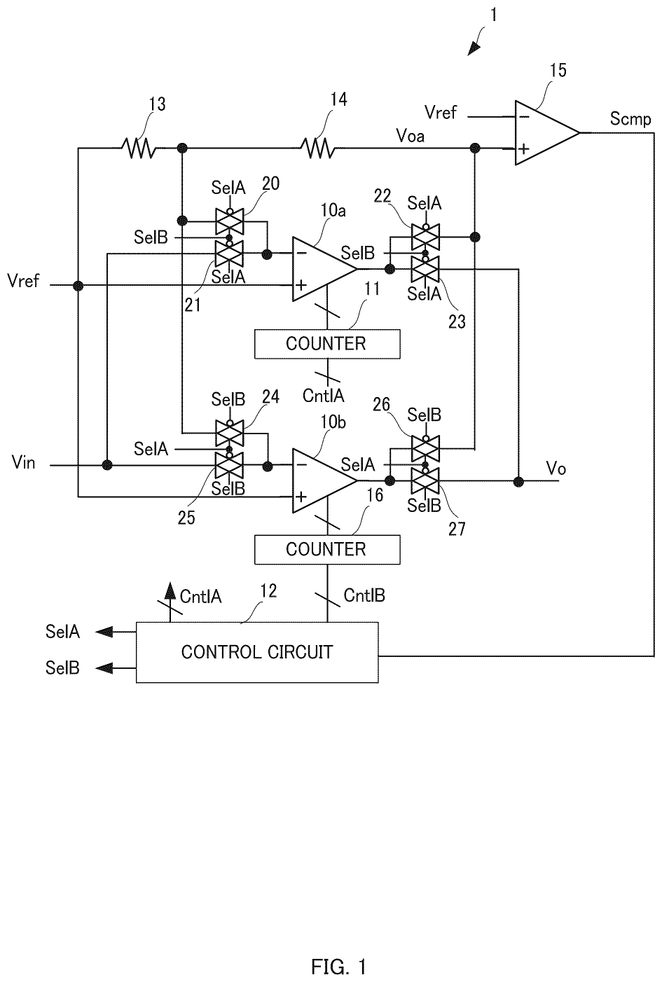

FIG. 1 is a diagram illustrating an example of a configuration of a signal processing circuit 1. The signal processing circuit 1 has two operational amplifiers and, while one of the operational amplifiers is processing an input signal, adjusts an offset of the other of the operational amplifiers. Specifically, based on the comparison result of a comparator 15 (described later), for example, when the offset adjustment of the operational amplifier 10a (described later) is completed, the signal processing circuit 1 causes the operational amplifier 10a to process the input signal while causing the operational amplifier 10b (described later) to stop processing the input signal, and performs the offset adjustment of the operational amplifier 10b in response to the signal with a period T. And vice versa, based on the comparison result of the comparator 15, for example, when the offset adjustment of the operational amplifier 10b is completed, the signal processing circuit 1 causes the operational amplifier 10b to process the input signal while causing the operational amplifier 10a to stop processing the input signal, and performs the offset adjustment of the operational amplifier 10a in response to the signal with the period T. The signal processing circuit 1 includes the operational amplifiers 10a, 10b, counters 11, 16, a control circuit 12, resistors 13, 14, the comparator 15, and analog switches 20 to 27.

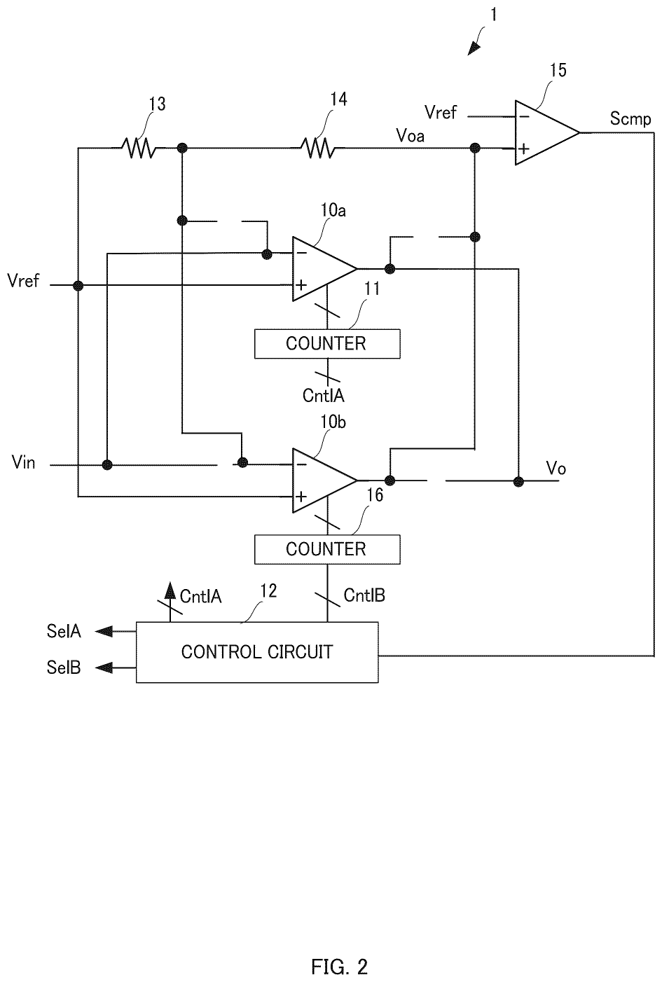

When the control circuit 12, described later, outputs a signal SelA at a high level (hereinafter referred to as high or high level) and a signal SelB at a low level (hereinafter referred to as low or low level), the operational amplifier 10a is selected to operate as an amplifier circuit and processes the input signal. Specifically, in this case, the operational amplifier 10a is used as the amplifier circuit that outputs an output voltage Vo corresponding to an input voltage Vin, as illustrated in FIG. 2.

On the other hand, when the control circuit 12 outputs a low signal SelA and a high signal SelB, the operational amplifier 10a is selected as a target of the offset adjustment, and the offset thereof is adjusted. Further, in this case, as will be described in detail later, the operational amplifier 10a is used for a non-inverting amplifier circuit and theoretically outputs a reference voltage Vref.

Further, when the control circuit 12, described later, outputs the low signal SelA and the high signal SelB, the operational amplifier 10b is selected to operate as an amplifier circuit, and processes the input signal. Specifically, in this case, the operational amplifier 10b is used as the amplifier circuit that outputs the output voltage Vo corresponding to the input voltage Vin.

Meanwhile, when the control circuit 12 outputs the high signal SelA and the low signal SelB, the operational amplifier 10b is selected as a target of the offset adjustment, and the offset thereof is adjusted. Further, in this case, as will be described in detail later, the operational amplifier 10b is used for a non-inverting amplifier circuit and theoretically outputs the reference voltage Vref.

==Configuration of Operational Amplifier 10a==

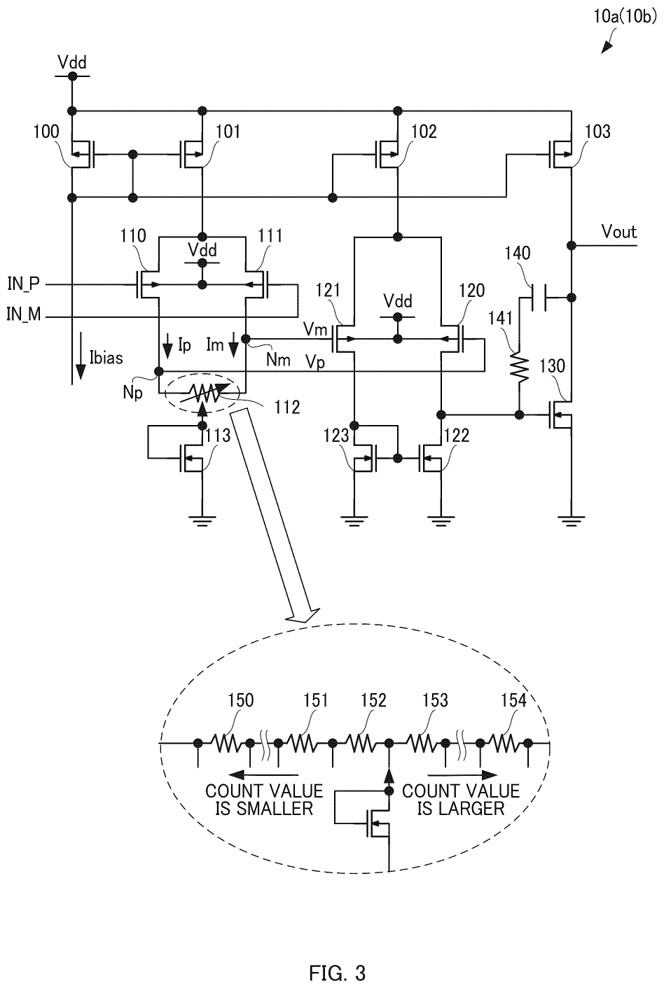

As illustrated in FIG. 3, the operational amplifier 10a includes P-channel metal-oxide-semiconductor (PMOS) transistors 100 to 103, 110, 111, 120, 121, a variable resistor 112, N-channel metal-oxide-semiconductor (NMOS) transistors 113, 122, 123, 130, a capacitor 140, and a resistor 141.

The PMOS transistors 100 to 103 configure a current mirror circuit. Specifically, a bias current Ibias flows through the PMOS transistor 100, and a current corresponding to the bias current Ibias flows through the PMOS transistors 101 to 103.

The PMOS transistors 110 and 111 configure a differential pair, and a voltage IN_P applied to the non-inverting input of the operational amplifier 10a and a voltage IN_M applied to the inverting input thereof are respectively applied to the gates of the PMOS transistors 110 and 111. Further, currents Ip and Im corresponding to the voltages IN_P and IN_M respectively applied to the PMOS transistors 110 and 111 flow through the PMOS transistors 110 and 111, respectively.

The variable resistor 112 is a circuit to adjust the offset of the operational amplifier 10a, based on a count value CNTa of the counter 11. The count value CNTa is a count value of the 8-bit counter 11 and changes in a range from 0 to 255, which will be described in detail later. Then, the variable resistor 112 is a resistor whose resistance value changes every time the count value CNTa changes by one, and thus includes 255 resistors having a predetermined resistance value (e.g., 1 kΩ) and 256 connection nodes to which the drain of the NMOS transistor 113 described later is to be connected. In FIG. 3, only five resistors 150 to 154 out of the 255 resistors are illustrated, for convenience.

Further, the variable resistor 112 changes the position of the connection node of the resistors to which the drain of the NMOS transistor 113 is to be connected, according to the count value CNTa. Accordingly, the variable resistor 112 generates, at the connection nodes Np and Nm respectively connected to the PMOS transistor 110 and 111, voltages Vp and Vm respectively corresponding to the currents Ip and Im and the count value CNTa. Thus, the variable resistor 112 operates to cancel out the offset of the PMOS transistors 120 and 121, which will be described in detail later. Specifically, the variable resistor 112 cancels the offset of the operational amplifier 10a by changing the connection node of the resistors to be connected with the drain of the NMOS transistor 113 according to the count value CNTa such that the voltages IN_P and IN_M will be equal. Thus, the operational amplifier 10a is an operational amplifier in which the offset thereof is adjustable.

The NMOS transistor 113 is a device that is diode-connected and operates as an active load of the differential pair configured with the PMOS transistors 110 and 111.

The PMOS transistors 120 and 121 configure a differential pair, and the gates thereof receive the voltages Vp and Vm, respectively. The NMOS transistors 122 and 123 are devices that operate as an active load of the differential pair configured with the PMOS transistors 120 and 121.

The NMOS transistors 122 and 123 are active devices configuring a current mirror circuit.

Further, the NMOS transistor 130 and the PMOS transistor 103 configures the output stage of the operational amplifier 10a, and the voltage Vout changes depending on the magnitude relationship between the current flowing from the PMOS transistor 103 and the current flowing from the NMOS transistor 130. That is, the PMOS transistor 103 and the NMOS transistor 130 function as a voltage divider circuit that outputs the voltage Vout varying with respective on-resistances thereof.

The capacitor 140 and the resistor 141 are elements for phase compensation and are connected in series between the drain and the gate of the NMOS transistor 130. In an embodiment of the present disclosure, the operational amplifier 10b has the same configuration as the operational amplifier 10a, and thus the description thereof is omitted.

The counter 11 in FIG. 1 is an 8-bit counter, which changes the count value CNTa in a range from 0 to 255, in response to a control signal CntlA from the control circuit 12, and controls the variable resistor 112 in the operational amplifier 10a.

The control circuit 12 outputs the control signal CntlA and a control signal CntlB, based on the comparison result of the comparator 15, described later, to thereby change the count value CNTa, CNTb of the counter 11, 16. Further, the control circuit 12 also outputs the signals SelA, SelB to select which of the operational amplifiers 10a and 10b is to operate as an amplifier circuit, to thereby control the analog switches 20 to 27.

The resistors 13 and 14 are elements to be used to adjust the offset of the operational amplifier 10b, when the operational amplifier 10a is selected to operate as an amplifier circuit, as illustrated in FIG. 2. A specific circuit used when adjusting the offset will be described as follows; the non-inverting input of the operational amplifier 10b receives the reference voltage Vref, and the inverting input thereof receives the voltage at the connection point between the resistors 13 and 14. Further, one end of the resistor 13 receives the reference voltage Vref, and the other end of the resistor 13 is connected with one end of the resistor 14. The other end of resistor 14 is connected to the output of the operational amplifier 10b. Further, the comparator 15 outputs a comparison result Scmp obtained by comparing a voltage Voa, which is the output of the operational amplifier 10b, with the reference voltage Vref. Note that the reference voltage Vref corresponds to a “predetermined voltage”.

In such a case, the following expressions hold:

$$Vinp = Vref \qquad Expression ( 1 )$$

$$Vinm = ( Voa - Vref ) \times ( R 1 / ( R 1 + R 2 ) ) + Vref , \qquad Expression ( 2 )$$

where Vinp is the voltage at the non-inverting input of the operational amplifier 10b, Vinm is the voltage at the inverting input, R1 is the resistance value of the resistor 13, and R2 is the resistance value of the resistor 14.

Further, the operational amplifier 10b operates such that the voltage Vinp and the voltage Vinm will be equal, and thus when using the Expressions (1) and (2), the following Expression holds:

$$Vref = ( Voa - Vref ) \times ( R 1 / ( R 1 + R 2 ) ) + Vref \qquad Expression ( 3 )$$

Accordingly, in theory, the voltage Voa is equal to the voltage Vref.

However, in the differential pair configured with the PMOS transistors 110 and 111 or the differential pair configured with the PMOS transistors 120 and 121 in FIG. 3, the respective threshold voltages thereof are different, and thus the offset voltage is generated in general. Thus, unlike the theoretical formula, the voltage Voa is not equal to the voltage Vref. The same applies to the operational amplifier 10a.

Thus, the control circuit 12 adjusts the count value CNTa, CNTb, to thereby adjust the offset of the operational amplifier 10a, 10b. Note that the operational amplifier 10a corresponds to a “first operational amplifier”, the operational amplifier 10b corresponds to a “second operational amplifier”, and the comparator 15 corresponds to a “comparator circuit”. Further, the count value CNTa, CNTb corresponds to “adjustment data”, and the variable resistor 112 corresponds to an “adjustment circuit”.

### ===Operation of Signal Processing Circuit 1===

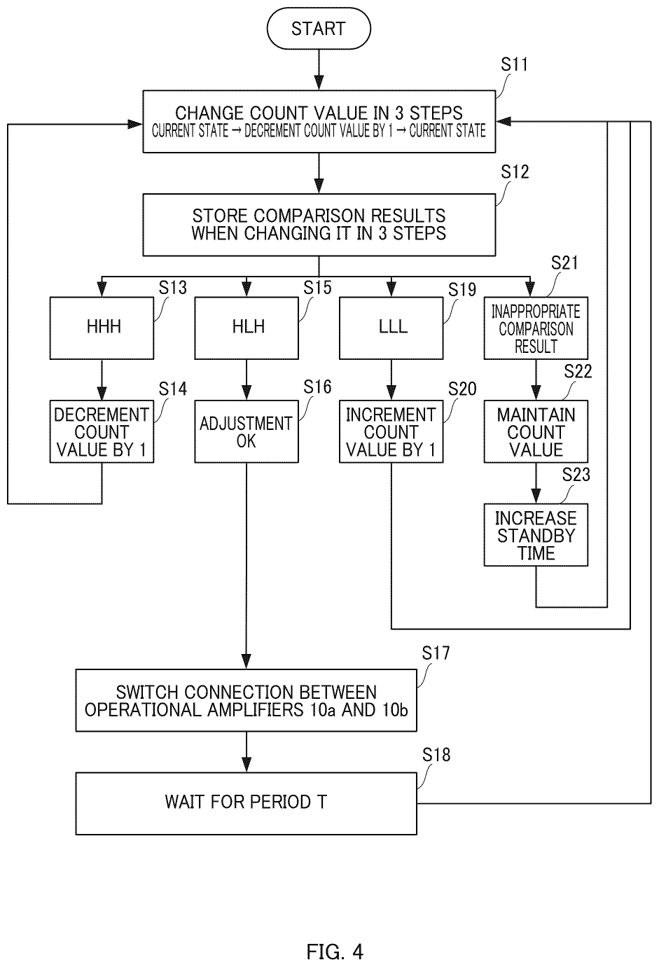

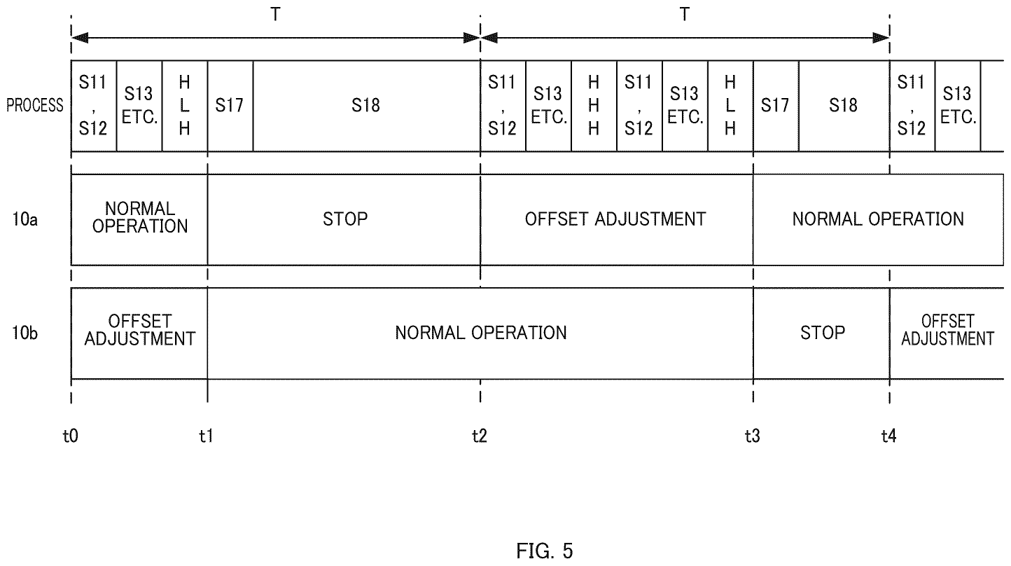

FIG. 4 is a diagram illustrating an example of a flowchart illustrating an operation of the signal processing circuit 1. FIG. 5 is a diagram illustrating an example of a timing chart when the offset adjustment is completed within the period T. In FIG. 4, it is assumed that the control circuit 12 outputs the high signal SelA and the low signal SelB such that the operational amplifier 10a is selected to operate as an amplifier circuit and the operational amplifier 10b is selected as the target of the offset adjustment. It is also assumed that the count value CNTb has already been set to an initial value (e.g., 128, which is midpoint between 0 and 255). Further, when each of the operational amplifiers 10a and 10b is selected as a target of the offset adjustment, an offset adjustment operation is started with the start of the period T (e.g., 80 ms) as a trigger. Note that the period T corresponds to a “predetermined period”.

The control circuit 12 performs a process triggered by the start of the period T to bring about a first state in which the count value CNTb is set to a predetermined count value, a second state in which the count value CNTb is set to the count value obtained by decrementing the predetermined count value by one, and a third state in which the count value CNTb is set to the predetermined count value (step S11). For example, when the count value CNTb is currently set to 128, the count value CNTb is set to 128 in the first and third states, and the count value CNTb is set to 127 in the second state. Note that the start of step S11 corresponds to time t0 in FIG. 5. Further, the predetermined count value corresponds to a “first value”, and the count value obtained by decrementing the predetermined count value by one corresponds to a “second value”.

After performing the process of bringing about the first to the third states, the control circuit 12 stores, in a storage circuit (not illustrated), each comparison result of the comparator 15 after a lapse of a standby time Ta, which is a predetermined time period (i.e., every time the first to third states are brought about, three comparison results, each obtained after a lapse of the standby time Ta, are stored together in the storage circuit) (step S12). Note that the standby time Ta corresponds to a “setting time”. Further, by storing the comparison result of the comparator 15 after a lapse of the standby time Ta, it is possible to store the comparison result in a state in which the operation of the operational amplifier 10b is stable.

The control circuit 12 checks the comparison result in the first to third states (steps S13, S15, S19, S21). Specifically, when all of the comparison results in the first to third states are high (step S13), the voltage Vout is higher than the reference voltage Vref, and thus the control circuit 12 decrements the count value CNTb by one (step S14). In other words, the count value CNTb decreases to 127. As such, in response to the count value CNTb decreasing, the voltage Vout drops. Then, the process returns to step S11.

Further, when the comparison results in the first and third states are high and the comparison result in the second state is low (step S15), the control circuit 12 determines that the offset adjustment has been performed correctly (i.e., the offset adjustment is OK) (step S16). Then, the control circuit 12 outputs the low signal SelA and the high signal SelB, to thereby switch the connection between the operational amplifiers 10a and 10b (step S17).

Specifically, in step S17, the signal processing circuit 1 changes from a state in which the operational amplifier 10a is selected to operate as an amplifier circuit and the operational amplifier 10b is selected as the target of the offset adjustment into a state in which the operational amplifier 10a is selected as the target of the offset adjustment and the operational amplifier 10b is selected to operate as an amplifier circuit. Thereafter, the signal processing circuit 1 waits for the period T to be elapsed (step S18). Then, the process returns to step S11. Note that the start of step S17 corresponds to time t1, t3 in FIG. 5.

As such, based on the comparison result, responsive to the offset adjustment of the operational amplifier 10b being completed, the control circuit 12 causes the operational amplifier 10a to perform the offset adjustment in response to the signal having the period T, while causing the operational amplifier 10b to process the input signal Vin, subsequent to the operational amplifier 10a. This operation corresponds to the operation at time t2 in FIG. 5.

In contrast, based on the comparison result, responsive to the offset adjustment of the operational amplifier 10a being completed, the control circuit 12 causes the operational amplifier 10b to perform the offset adjustment in response to the signal having the period T, while causing the other operational amplifier 10a to process the input signal Vin, subsequent to the operational amplifier 10b. This operation corresponds to the operation at time t4 in FIG. 5.

On the other hand, when all of the comparison results in the first to third states are low (step S19), the voltage Vout is lower than the reference voltage Vref, and thus the control circuit 12 increments the count value CNTb by one (step S20). In other words, the count value CNTb increases to 129. As such, in response to the count value CNTb increasing, the voltage Vout rises. Then, the process returns to step S11.

Further, upon determining that the comparison results in the first and third states are not the same, the control circuit 12 determines that the comparison results are inappropriate (step S21). Here, the term “inappropriate comparison results” refers to that the comparison results of the comparator 15 are different even though the count values CNTb are the same. On the other hand, in an embodiment of the present disclosure, the “appropriate comparison results” refer to that the comparison results of the comparator 15 are the same when the count values CNTb are the same.

In general, when the variable resistor 112 is changed based on the count value CNTb, it takes a certain amount of time for the output of the operational amplifier 10b to stabilize. If the count value CNTb is changed by only one count; the variable resistor 112 is changed; and the comparison result of the comparator 15 is immediately obtained, the comparison result may be acquired before the output of the operational amplifier 10b obtained, and the comparison result may be different from the logic level it should be.

Thus, thereafter, while the count value CNTb being maintained (step S22), the standby time Ta after changing from the first state to the third state is increased (i.e., the standby time Ta is increased longer than the initial value) (step S23). Then, the process returns to step S11. With such an operation being performed, in an embodiment of the present disclosure, it is possible to confirm whether the comparison result has been obtained after the output of the operational amplifier 10b has stabilized, by obtaining the comparison results at the same count value CNTb in the first and third states and comparing the comparison results in respective states.

The operation is performed as described above, and when determining that the comparison result in the first state is the same as the comparison result in the third state, the control circuit 12 updates the count value CNTb and performs the process until it is determined that either the comparison result in the first state or the comparison result in third states is not the same as the comparison result in the second state.

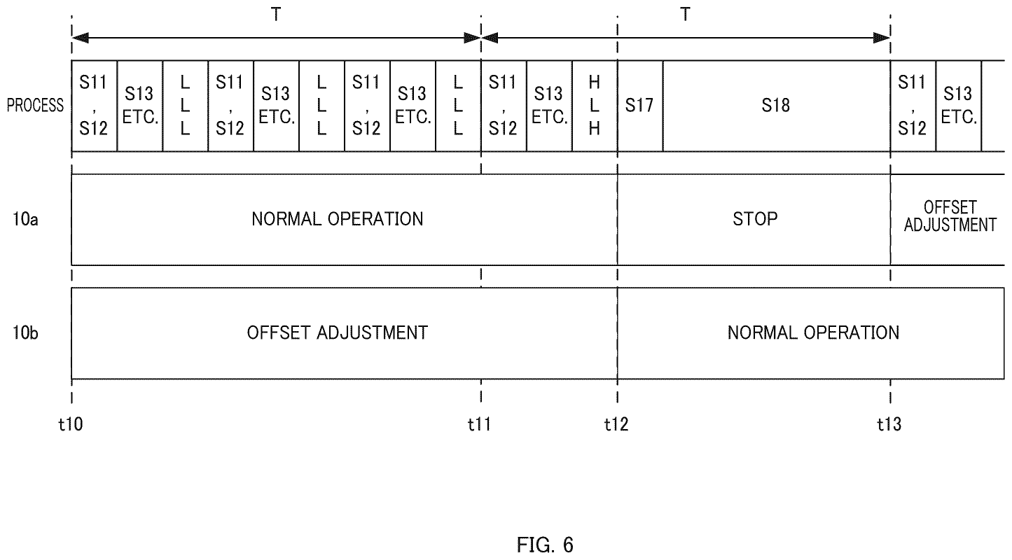

Meanwhile, as illustrated in FIG. 6, when the offset adjustment of the operational amplifier 10b is not finished during the period T (time t1l), the offset adjustment continues (time t10 to t12) until the offset adjustment is finished. Then, responsive to the offset adjustment of the operational amplifier 10b being finished, the operational amplifier 10a stops a normal operation serving as an amplifier circuit, and the operational amplifier 10b starts the normal operation as the amplifier circuit (time t12).

Then, after a lapse of the period T, the operational amplifier 10a starts the offset adjustment, and the operational amplifier 10b continues the normal operation (time t13) as the amplifier circuit until the offset adjustment of the operational amplifier 10a is finished.

With the signal processing circuit 1 being operated as such, it is possible to provide a signal processing circuit capable of processing the input signal with high precision.

### Modification

In an embodiment of the present disclosure, responsive to the count value CNTb changing by one, the connection node between the variable resistor 112 and the drain of the NMOS transistor 113 shifts by one, but the present disclosure is not limited thereto, and in order to shift the connection node by one, the control circuit 12 may change the count value CNTb by two.

### Summary

The signal processing circuit 1 according to an embodiment of the present disclosure has been described above. The signal processing circuit 1 includes the operational amplifiers 10a, 10b, the comparator 15, and the control circuit 12. The control circuit 12 is configured to, upon completion of the offset adjustment of the operational amplifier (e.g., the operational amplifier 10b) selected as a target of the offset adjustment, for example, cause the operational amplifier 10b to process the input signal while causing the operational amplifier 10a to stop processing the input signal and perform the offset adjustment of the operational amplifier 10a in response to the signal having the period T, based on the signal Scmp, with the period T serving as a trigger. Further, the control circuit 12 causes the operational amplifiers 10a, 10b to perform the operations that are interchanged. This makes it possible to provide the signal processing circuit capable of processing the input signal with high precision.

Further, the signal processing circuit 1 also includes the variable resistor 112 configured to adjust the offset of the operational amplifier (e.g., operational amplifier 10b) selected as a target of the offset adjustment, based on the count value (e.g., count value CNTb). Further, the control circuit 12 performs a process of storing, in the storage circuit, the comparison result of the operational amplifier to be subjected to the offset adjustment in the comparator 15 as the first and third states in which the count value CNTb is set to, for example, 128; and storing, in the storage circuit, the comparison result of the operational amplifier to be subjected to the offset adjustment in the comparator 15, as the second state in which the count value CNTb is set to, for example, 127, and then determines whether the comparison results (signals Scmp) in the first and third states are the same. This makes it possible to determine whether the standby time Ta, which is after the predetermined state is set until when the comparison result is obtained, is sufficiently long.

Further, when the control circuit 12 determines that the comparison result in the first state and the comparison result in the second states are not the same, the standby time Ta is increased longer than the initial value and performs step S11 in FIG. 4. Accordingly, the standby time Ta is set sufficiently long, and the comparison result is obtained in a state in which the operations of the operational amplifiers 10a, 10b are stable, and thus the offset adjustment is performed correctly.

Further, when determining that the comparison result in the first state and the comparison result in the third state are the same, the control circuit 12 updates the count value (e.g., count value CNTb) and repeats the offset adjustment until determining that either the comparison result in the first state or the comparison result in the third state is not the same as the comparison result in the second state. This makes it possible to perform the offset adjustment, taking into account the temperature characteristics of the offset voltage.

Further, the signal processing circuit 1 also includes the amplifier circuit that uses the operational amplifier 10a (or the operational amplifier 10b), the variable resistor 112, the comparator 15, and the control circuit 12. The control circuit 12 performs a process of storing, in the storage circuit, the comparison result of the operational amplifier to be subjected to the offset adjustment in the comparator 15 as the first and third states in which the count value CNTb is set to, for example, 128; and storing, in the storage circuit, the comparison result of the operational amplifier to be subjected to the offset adjustment in the comparator 15 as the second state in which the count value CNTb is set to, for example, 127, and then determines whether the comparison results (signals Scmp) in the first and third states are the same. This makes it possible to determine whether the standby time Ta, which is after the predetermined state is set until when the comparison result is obtained, is sufficiently long.

Further, when the control circuit 12 determines that the comparison result in the first state and the comparison result in the second states are not the same, the standby time Ta is increased longer than the initial value and performs step S11 in FIG. 4. Accordingly, the standby time Ta is set sufficiently long, and the comparison result is obtained in a state in which the operations of the operational amplifiers 10a, 10b are stable, and thus the offset adjustment is performed correctly.

Further, when determining the comparison result in the first state and the comparison result in the third state are the same, the control circuit 12 updates the count value (e.g., count value CNTb) and repeats the offset adjustment until determining that either the comparison result in the first state or the comparison result in the third state is not the same as the comparison result in the second state. This makes it possible to perform the offset adjustment, taking into account the temperature characteristics of the offset voltage.

The present disclosure is directed to provision of a signal processing circuit capable of processing an input signal with high precision.

According to the present disclosure, it is possible to provide a signal processing circuit capable of processing an input signal with high precision.

An embodiment of the present disclosure described above is simply to facilitate understanding of the present disclosure and is not in any way to be construed as limiting the present disclosure. The present disclosure may variously be changed or altered without departing from its essential features and encompass equivalents thereof.

What is claimed is:

1. A signal processing circuit, comprising:
a first operational amplifier and a second operational amplifier, each configured to perform offset adjustment thereof, and each being selectable to operate as an amplifier circuit to output an output voltage corresponding to an input voltage thereof;
a comparator circuit configured to output a comparison result obtained by comparing the output voltage of the amplifier circuit and a predetermined voltage; and
a control circuit configured to,
upon completion of the offset adjustment of the first operational amplifier, cause the first operational amplifier to process an input signal of the signal processing circuit, while causing the second operational amplifier to stop processing the input signal and to perform the offset adjustment thereof in response to a signal having a predetermined period, based on the comparison result, and
upon completion of the offset adjustment of the second operational amplifier, cause the second operational amplifier to process the input signal, while causing the first operational amplifier to stop processing the input signal and to perform the offset adjustment thereof in response to the signal having the predetermined period, further based on the comparison result.

2. The signal processing circuit according to claim 1, wherein
each of the first and second operational amplifiers includes an adjustment circuit that is configured to perform the offset adjustment thereof, based on a value of adjustment data, and
the control circuit
performs a process of
storing a first comparison result that is the comparison result of the comparator circuit in a first state in which the value of the adjustment data is set to a first value;
storing a second comparison result that is the comparison result of the comparator circuit in a second state in which the value of the adjustment data is set to a second value; and
storing a third comparison result that is the comparison result of the comparator circuit in a third state in which the value of the adjustment data is set to the first value, and
subsequently determines whether the first comparison result and the third comparison result are the same.

3. The signal processing circuit according to claim 2, wherein upon determining that the first comparison result and the third comparison result are not the same, the control circuit increases a setting time for setting each of the first state, the second state and the third state to be longer than an initial value and performs the process.

4. The signal processing circuit according to claim 3, wherein upon determining that the first comparison result and the third comparison result are the same, the control circuit updates the first value and the second value and performs the process, until either the first comparison result or the third comparison result is different from the second comparison result.

5. A signal processing circuit, comprising:
an amplifier circuit configured to output an output voltage corresponding to an input voltage, using an operational amplifier;
an adjustment circuit configured to adjust an offset of the operational amplifier, based on a value of an adjustment data;
a comparator circuit configured to output a comparison result obtained by comparing the output voltage and a predetermined voltage; and
a control circuit configured to
perform a process of
storing a first comparison result that is the comparison result of the comparator circuit in a first state in which the value of the adjustment data is set to a first value;
storing a second comparison result that is the comparison result of the comparator circuit in a second state in which the value of the adjustment data is set to a second value; and
storing a third comparison result that is the comparison result of the comparator circuit in a third state in which the value of the adjustment data is set to the first value, and
subsequently determine whether the first comparison result and the third comparison result are the same.

6. The signal processing circuit according to claim 5, wherein upon determining that the first comparison result and the third comparison result are not the same, the control circuit increases a setting time for setting each of the first state, the second state and the third state to be longer than an initial value and performs the process.

7. The signal processing circuit according to claim 6, wherein upon determining that the first comparison result and the third comparison result are the same, the control circuit updates the first value and the second value and performs the process, until either the first comparison result or the third comparison result is different from the second comparison result.
